(19) United States
(12) Patent Application Publication
(10) Pub. No.: US 2016/0240398 A1
(43) Pub. Date: Aug. 18, 2016

(54) Wafer Holder

(71) Applicant: HERMES-EPITEK CORPORATION, Taipei (TW)

(72) Inventors: Takahiro Oishi, Kanagawa (JP); Kian-Poh Wong, Tainan City (TW); Tsan-Hua Huang, Tainan City (TW); Shih-Yung Shieh, Xinzhu City (TW)

(73) Assignee: HERMES-EPITEK CORPORATION

(21) Appl. No.: 14/703,113

(22) Filed: May 4, 2015

(30) Foreign Application Priority Data
Feb. 12, 2015 (TW) 104104677

(51) Int. Cl. H01L 21/673

(52) U.S. Cl. CPC H01L 21/673

(57) ABSTRACT

A wafer holder includes a holder main body, a supporting member, and a limiting member. The holder main body has a through hole region. The supporting member has a supporting main body and supporting legs. The supporting main body is disposed on an inner surface of the through hole region, and the supporting legs are attached to an inner surface of the supporting main body and configured to support a wafer. The limiting member is attached to the supporting main body and disposed between two adjacent supporting legs and opposite to a flat side of the wafer.

### CLAIM OF PRIORITY

The present application claims priority from Taiwan Application No. 104104677, filed on Feb. 12, 2015 and entitled “WAFER HOLDER”, the contents of which are expressly incorporated herein by reference in their entirety.

### BACKGROUND OF THE DISCLOSURE

1. Field of the Disclosure

The invention generally relates to a wafer holder, and more particularly to a wafer holder for preventing a wafer from rotating.

2. Description of Related Art

FIG. 1A shows a cross-sectional view of a conventional wafer holder 100, and FIG. 1B shows a wafer 140 processed using a conventional manufacturing process. The wafer holder 100 includes a holder main body 110 and a plurality of supporting members 120. The supporting members 120 are disposed on an inner surface of the holder main body 110. In the manufacturing process, the wafer 140 is placed face down on the supporting members 120. Thus, as shown in FIG. 1B, the wafer 140 might have pressure marks 142A corresponding to top surfaces of the supporting members 120.

However, as the wafer 140 needs to be kept in a high-temperature state during the manufacturing process, the wafer 140 is generally heated from a top opening 130 of a wafer holder 100, and a reactive gas is applied to a surface of the wafer 140 for epitaxial growth. The wafer 140 rotates or moves in any direction due to thermal deformation or the impact effect of the reactive gas, and the surface of the wafer 140 may correspondingly have marks 142B caused by an Epi film. Consequently, the usable surface area of the wafer 140 may be reduced.

A need has thus arisen to address defects of a conventional wafer holder.

### SUMMARY

In view of the foregoing, embodiments of the disclosure provide a wafer holder to reduce or prevent a wafer from rotating or moving, e.g., in a random direction, and from incurring marks, e.g., pressure marks, during a manufacturing process of the wafer. The wafer holder may improve a production yield and increase a usable area of the wafer.

According to one embodiment of the disclosure, a wafer holder includes a holder main body, a supporting member, and a limiting member. The holder main body includes a through hole region. The supporting member includes a supporting main body and a plurality of supporting legs. The supporting main body is disposed on the through hole region, and the supporting legs are evenly attached to an inner surface of the supporting main body and configured to support a wafer. The limiting member is attached to the supporting main body and disposed between two adjacent supporting legs. The limiting member is opposite to a flat side of the wafer to prevent or restrict the wafer from rotating.

### BRIEF DESCRIPTION OF THE DRAWINGS

FIG. 1A shows a cross-sectional view of a conventional wafer holder.

FIG. 1B shows a wafer processed under conventional manufacturing conditions.

FIG. 2A shows a partial perspective view of a wafer holder according to an embodiment of the disclosure.

FIG. 2B shows a top view of the wafer holder of FIG. 2A.

FIG. 2C shows a view of a wafer disposed on the wafer holder of FIG. 2A.

FIG. 2D shows a view of an isothermal plate and a wafer both disposed on the wafer holder of FIG. 2A.

FIG. 3A shows a partial perspective view of a wafer holder according to another embodiment of the disclosure.

FIG. 3B shows a view of a wafer disposed on the wafer holder of FIG. 3A.

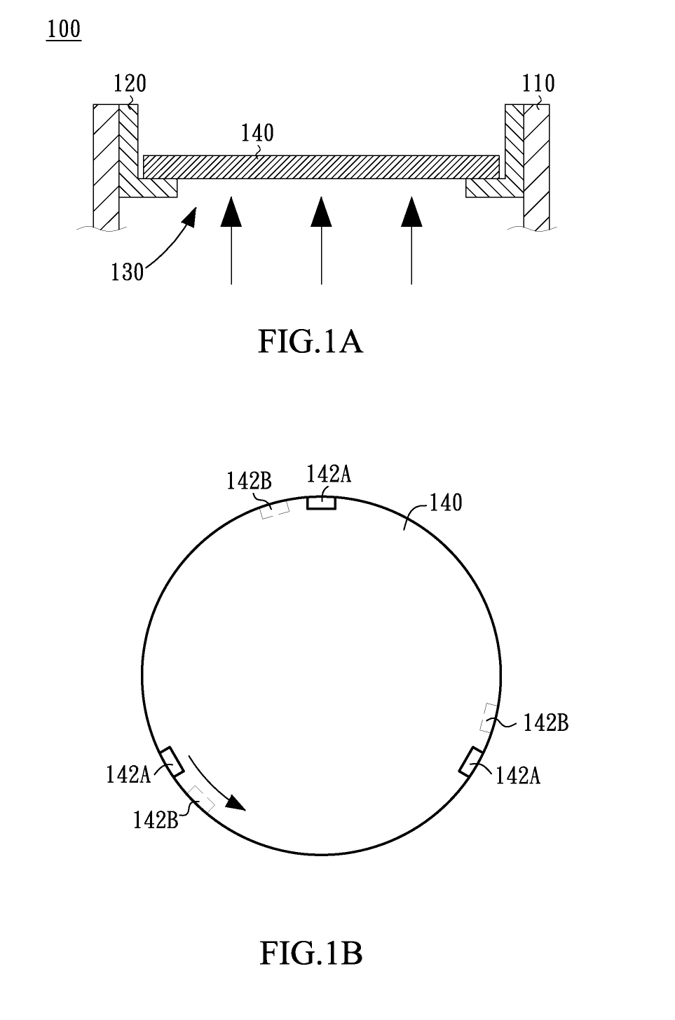

### DETAILED DESCRIPTION

The description provided in reference to the following embodiments is not intended to limit the scope of the invention, which can be adapted for other applications. Although drawings are illustrated in detail, it is appreciated that aspects and features in the description or drawings may vary from that disclosed. For example, a characteristic or quantity of a component may differ or be greater or less than that disclosed absent an express restriction of the characteristic or quantity.

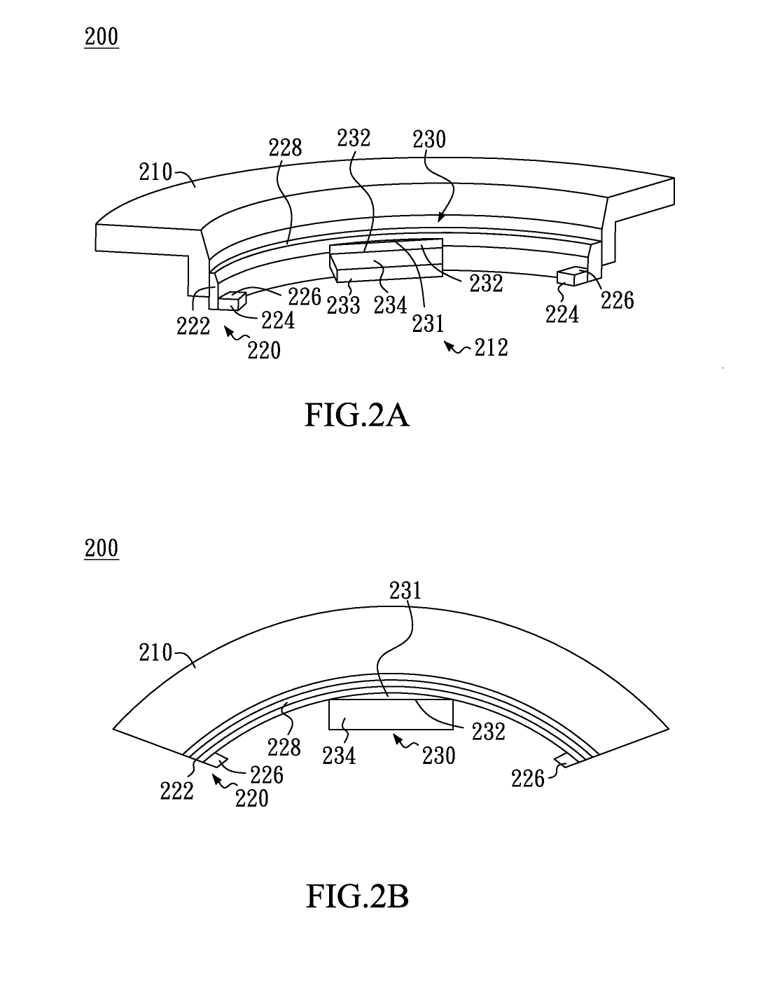

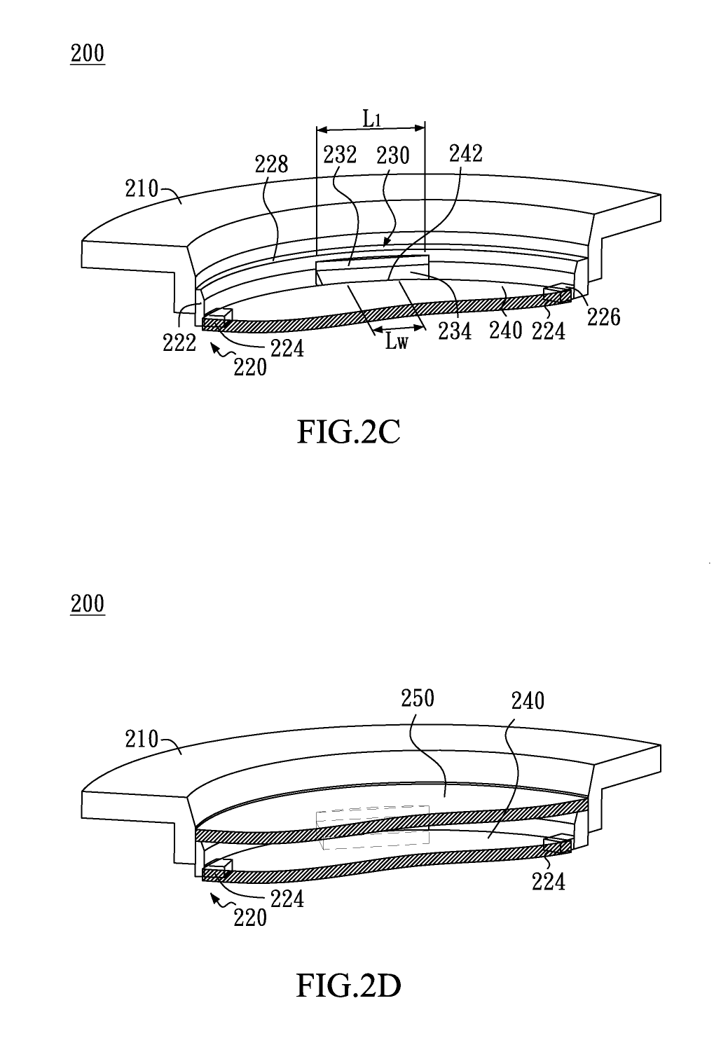

FIGS. 2A-2C show sundry views of a wafer holder 200 according to an embodiment of the disclosure. FIG. 2A shows a partial perspective view of the wafer holder 200, FIG. 2B shows a top view of the wafer holder 200, and FIG. 2C shows an additional view of the wafer holder 200 combined with a wafer 240. As illustrated in FIGS. 2A-2C, the wafer holder 200 includes a holder main body 210, a supporting member 220, and a limiting member 230. The holder main body 210 has a through hole region 212. The supporting member 220 includes a supporting main body 222 and a plurality of supporting legs 224. The supporting main body 222 is disposed on the through hole region 212, and the supporting legs 224 are evenly spaced and attached to an inner surface of the supporting main body 222, in order to support the wafer 240. The limiting member 230 is attached to the supporting main body 222 and disposed between two adjacent supporting legs 224. Furthermore, the limiting member 230 is disposed opposite to a flat side 242 of the wafer 240, in order to prevent or restrict the wafer 240 from rotating. Further, in one embodiment, any combination of the holder main body 210, the supporting member 220, and the limiting member 230 may be formed integrally, according to an actual design or need.

Each supporting leg 224 may have a first supporting surface 226, which is configured to support the wafer 240. The supporting main body 222 and the supporting legs 224 may be formed integrally, according to an actual design or need. In addition, the limiting member 230 may include a limiting main body 231, and the limiting main body 231 may have a limiting surface 232, which is opposite to the flat side 242 of the wafer 240, for preventing or restricting the wafer 240 from rotating.

In the illustrated embodiment, the limiting member 230 may further include a supporting block 233, which is located on a bottom end of the limiting surface 232 of the limiting main body 231. The supporting block 233 has a top surface 234, which is configured to support the wafer 240. According to an aspect, the top surface 234 of the supporting block 233 may have substantially the same height level as the first supporting surfaces 226 of supporting legs 224. Therefore, when the wafer 240 is disposed on the wafer holder 200, the wafer 240 can be simultaneously disposed and supported on the first supporting surfaces 226 of the supporting legs 224 and on the top surface 234 of the supporting block 233.

As depicted in FIG. 2C, when the wafer 240 is influenced to outwardly move or expand, e.g., via thermal deformation or an impact effect of a reactive gas, the flat side 242 of the wafer 240 may abut against the limiting surfaces 332 of the limiting main body 231. Hence, the wafer 240 may be hindered or prevented from rotation or movement, e.g., in any direction. In one embodiment, a gap between the limiting surface 232 and the flat side 242 of the wafer 240 is between 0.05 mm and 1 mm. Moreover, in the embodiment illustrated in FIG. 2C, a length (L1) of the limiting surface 232 is greater than a length (Lw) of the flat side 242 of the wafer 240. The invention is not limited to the enumerated dimensions. For example, the length (L1) of the limiting surface 232 can be adjusted to be less than or equal to the length (Lw) of the flat side 242 of the wafer 240, according to an actual need, e.g., of a manufacturing process.

FIG. 2D shows a view of an isothermal plate 250 and the wafer 240 both disposed on the wafer holder 200 of FIG. 2A. As shown in FIG. 2D, the wafer holder 200 can further include the isothermal plate 250, and the isothermal plate 250 can be disposed on a second supporting surface 228 of the supporting main body 222 of the supporting member 220. The second supporting surface 228 is above the first supporting surface 226. Therefore, heating of the wafer 240 from the top of the wafer holder 200 may cause a gas thermal convection in the cavity between the isothermal plate 250 and the wafer 240, and may result in a surface of the wafer 240 being relatively uniformly heated and a process yield being effectively improved.

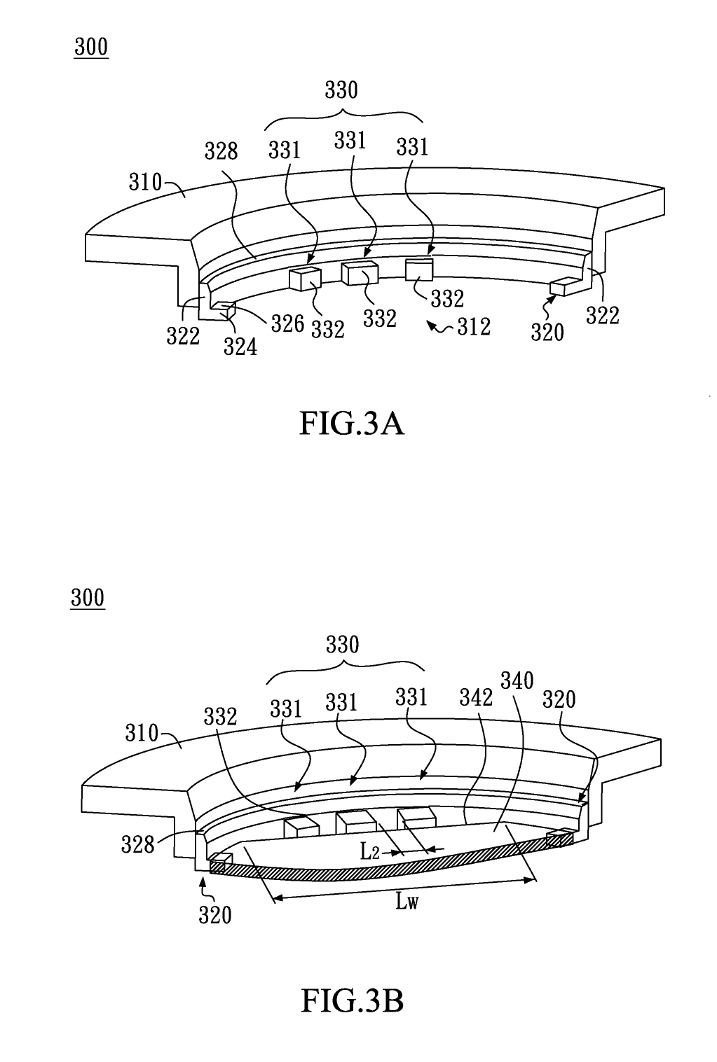

FIG. 3A shows a partial perspective view of a wafer holder 300 according to another embodiment of the disclosure, and FIG. 3B shows a view of a wafer 340 disposed on the wafer holder 300. As shown in FIGS. 3A and 3B, the limiting member 330 may include a plurality of limiting blocks 331. The limiting blocks 331 are evenly disposed on the inner surface of the supporting main body 322. Each limiting block 331 has a limiting surface 332, which is opposite to a flat side 342 of the wafer 340. The limiting blocks 331 may be located on the inner surface of the supporting main body 322 at substantially the same height. Accordingly, as the wafer 340 is influenced to move or expand, e.g., outwardly, such as by thermal deformation or an impact effect via a reactive gas, the flat side 342 of the wafer 340 will abut against the limiting surfaces 332 of the limiting blocks 331, so that the wafer 340 cannot or has a diminished capacity to rotate or move in any direction. In one embodiment, a gap between the limiting blocks 331 and the flat side 342 of the wafer 340 may be between 0.05 mm to 1 mm.

Furthermore, as shown in FIG. 3B, a gap (L2) between every two adjacent limiting blocks 331 may be less than or equal to a length (Lw) of the flat side 342 of the wafer 340. Thus, when the wafer 340 is outwardly expanded because of thermal deformation, the surfaces 332 of the limiting blocks 331 will abut against the flat side 342 of the wafer 340 to effectively limit rotation or displacement of the wafer 34, so that pressure marks on the wafer 340 may be reduced or avoided.

Although specific embodiments have been illustrated and described, it will be appreciated by those skilled in the art that various modifications may be made without departing from the scope of the invention, which is intended to be limited solely by the appended claims and their equivalents.

What is claimed is:

1. A wafer holder, comprising:
a holder main body having a through hole region;
a supporting member wherein the supporting member comprises:
a supporting main body disposed on the through hole region; and
a plurality of supporting legs attached to an inner surface of the supporting main body and configured to support a wafer; and
a limiting member attached to the supporting main body and disposed between two adjacent supporting legs, wherein the limiting member is opposite to a flat side of the wafer.

2. The wafer holder of claim 1, wherein the plurality of supporting legs are substantially evenly spaced on the inner surface, and wherein each of the plurality of supporting legs has a first supporting surface for supporting the wafer.

3. The wafer holder of claim 1, wherein the limiting member comprises a limiting main body, the limiting main body has a limiting surface, and the limiting surface is opposite to the flat side of the wafer, so as to prevent the wafer from rotating.

4. The wafer holder of claim 3, wherein a gap between the limiting surface and the flat side of the wafer is between 0.05 mm to 1 mm.

5. The wafer holder of claim 1, wherein the limiting member comprises:
a supporting block, located on a bottom end of a limiting surface, wherein the supporting block has a top surface for supporting the wafer.

6. The wafer holder of claim 1, wherein the plurality of supporting legs have a plurality of first supporting surfaces , and further comprising an isothermal plate, disposed on a second supporting surface of the supporting main body, the second supporting surface located above the plurality of first supporting surfaces.

7. The wafer holder of claim 1, wherein the limiting member comprises:
a plurality of limiting blocks substantially evenly spaced on the inner surface of the supporting main body, wherein each limiting block has a limiting surface opposite to the flat side of the wafer.

8. The wafer holder of claim 7, wherein each of the limiting surfaces has a width, and wherein the widths of the limiting surfaces are the same.

9. The wafer holder of claim 7, wherein each gap between two adjacent limiting blocks is less than or equal to a length of the flat side of the wafer.

10. The wafer holder of claim 7, wherein a gap between the limiting surfaces of the limiting blocks and the flat side of the wafer is between 0.05 mm to 1 mm.
